(19) United States
(12) Patent Application Publication
(10) Pub. No.: US 2004/0072442 A1
(43) Pub. Date: Apr. 15, 2004

(54) Low-bias bottom electrode etch for patterning ferroelectric memory elements

(76) Inventors: Francis Gabriel Celii, Dallas, TX (US); Mahesh Thakre, Dallas, TX (US); Scott R. Summerfelt, Garland, TX (US)

Correspondence Address: TEXAS INSTRUMENTS INCORPORATED, P O BOX 655474, M/S 3999, DALLAS, TX, 75265

(21) Appl. No.: 10/270,913

(22) Filed: Oct. 15, 2002

(51) Int. Cl. H01L 21/302; H01L 21/461

(52) U.S. Cl. 438/710

(57) ABSTRACT

One aspect of the invention relates to a method of manufacturing FeRAM, and in particular, plasma etching a bottom electrode layer in a ferroelectric capacitor stack. According to the method, plasma etching is carried out at a relatively low bias in an atmosphere that includes a halogen compound and an oxygen source containing carbon, such as carbon monoxide or carbon dioxide. The invention prevents shorting along the sidewalls of the capacitor stack, which can otherwise be caused by re-deposition of material released from the bottom electrode layer. The gas composition and temperature are such that chemical reaction substantially contributes to the etch rate as compared to purely physical etching. In one embodiment, the capacitor stack is etched with a hard mask that include TiAlN and the atmosphere is oxidizing to an extent that increases the selectivity between the hard mask and the bottom electrode layer.

### FIELD OF THE INVENTION

The present invention relates generally to the field of integrated circuit processing, and more particularly relates to a method of manufacturing FeRAM devices.

### BACKGROUND OF THE INVENTION

The semiconductor industry has long faced a demand for small, portable personal devices. These devices include cellular phones, personal computing equipment, and personal sound systems, which are sought in continuously smaller sizes and with continuously lower power requirements. At the same time that smaller and more portable personal devices are sought, computational power and on-chip memory requirements are increasing. In light of these requirements, there has been a long-felt need for computational devices that have substantial memory and logic functions integrated within individual semiconductor chips. Preferably, the memory is configured such that if power is interrupted, as when a battery fails, the contents of the memory are retained. Memory that retains its content without a continuous supply of power is called non-volatile memory. Conventional non-volatile memory types include electrically erasable programmable read only memory (EEPROM) and flash EEPROM.

Ferroelectric random access memory (FeRAM) is a type of non-volatile memory that stores data in memory cells that include capacitors with ferroelectric cores. A ferroelectric core contains a ferroelectric material, such as SBT or PZT, as the dielectric. The non-volatility of an FeRAM results from the bi-stable characteristic of ferroelectric materials.

There are single and dual capacitor ferroelectric memory cells. The single capacitor memory cell (referred to as a 1T/1C or 1C memory cell) requires less silicon area and thereby increases the potential density of the memory array, but is less immune to noise and process variations. A 1C cell requires a voltage reference for determining a stored memory state. The dual capacitor memory cell (referred to as a 2T/2C or 2C memory cell) requires more silicon area and stores complementary signals allowing differential sampling of the stored information. The 2C memory cell is more stable than the 1C memory cell.

As illustrated in prior art FIG. 1, a 1T/1C FeRAM cell 100 includes a transistor 110 and a ferroelectric storage capacitor 120. The transistor 110 includes a gate 112, a source 114, and a drain 116. The storage capacitor 120 includes a bottom electrode 122, a top electrode 124, and a ferroelectric core. The drain 116 of the transistor 110 is connected to the bottom electrode 122 of the capacitor 120. The source 114 of the transistor 110 is connected to a bit line 132 (BL). The 1T/1C cell 100 is read by applying a signal to the gate 112 through a word line 130 (WL), switching on the transistor 110. This brings the bottom electrode 122 of the capacitor 120 into communication with the bit line 132. Then, through a drive line 134 (DL), a pulse signal is applied to the top electrode 124 of the capacitor 120. The potential on the bit line 132 becomes the capacitor charge divided by the bit line capacitance. Since the capacitor charge is dependent upon the bi-stable polarization state of the ferroelectric core, the bit line potential can have two distinct values. A sense amplifier (not shown) is connected to the bit line 132 and detects the voltage associated with a logic value of either 1 or 0. Frequently the sense amplifier reference voltage is a ferroelectric or non-ferroelectric capacitor connected to another bit line that is not being read.

Prior art FIG. 2, illustrates a 2T/2C memory cell 200. The memory cell 200 comprises two transistors 202 and 204 and two ferroelectric capacitors 206 and 208, respectively. The first transistor 202 couples between a bit line 210 and the first capacitor 206. The second transistor 204 couples between a bit line-bar 212 and the second capacitor 208. The capacitors 206 and 208 are connected to a common drive line 214 (DL), to which a signal is applied for polarizing the capacitors.

In a write operation, the first and second transistors 202 and 204 of the dual capacitor ferroelectric memory cell 200 are enabled via a word line 216 (WL) to couple the capacitors 206 and 208 to the complementary logic levels on the bit line 210 and the bit-bar line 212. The common drive line 214 of the capacitors is pulsed during the write operation to polarize the dual capacitor memory cell 200 to one of two logic states.

In a read operation, the first and second transistors 202 and 204 are enabled via the word line 216 to couple the information stored on the first and second capacitors 206 and 208 to the bit line 210 and the bit line-bar line 212, respectively. A differential signal (not shown) is thus generated across the bit line 210 and the bit line-bar line 212. A sense amplifier (not shown) senses the differential signal and determines the logic level stored in memory.

Forming FeRAM devices presents several challenges. The ferroelectric capacitor alone requires many separate layers. In addition to the ferroelectric core and top and bottom electrode layers, a ferroelectric capacitor may require diffusion barrier layers. The electrodes may include multiple sub-layers to address resistance, processing, and material compatibility requirements. Limiting the number, duration, and complexity of processing steps required to form these various layers is highly desirable.

Plasma etching of an iridium layer (sometimes employed as FeRAM capacitor electrodes) has been known to result in the formation of a conductive layer along plasma etching chamber sidewalls, which can interfere with chamber operation. It has been suggested that adding CO to the plasma atmosphere can mitigate this problem. However, there remains a long felt unmet need for better processes of forming ferroelectric capacitor stacks.

### SUMMARY OF THE INVENTION

The following presents a simplified summary in order to provide a basic understanding of some aspects of the invention. This summary is not an extensive overview of the invention. It is intended neither to identify key or critical elements of the invention nor to delineate the scope of the invention. Rather, the primary purpose of this summary is to present some concepts of the invention in a simplified form as a prelude to the more detailed description that is presented later.

One aspect of the invention relates to a method of manufacturing an FeRAM, and in particular, plasma etching a bottom electrode layer in a ferroelectric capacitor stack. According to the method, plasma etching is carried out at a relatively low bias with an atmosphere that includes a halogen compound and carbon monoxide. The invention prevents shorting along the sidewalls of the capacitor stack, which can otherwise be caused by re-deposition of material released from the bottom electrode layer. The gas composition and temperature are such that chemical reaction substantially contributes to the etch rate as compared to purely physical etching.

In one embodiment, the process is carried out at a temperature and gas composition whereat reaction with the carbon monoxide substantially prevents conductive material from depositing on the capacitor stack side walls. In another embodiment, conductive material from the bottom electrode layer deposits on the capacitor stack side walls during the etch process, but reaction of the deposited material with the carbon monoxide prevents the buildup of a substantially conductive layer. In yet another embodiment, a conductive layer does form on the capacitor side walls, but the composition thereof is such that the side wall material is readily removed, for example, via a, subsequent wet clean.

In a further embodiment, the capacitor stack is etched with a hard mask containing TiAlN and the atmosphere is oxidizing to an extent that increases the selectivity between the hard mask and the bottom electrode layer. An oxide crust forms on the hard mask. For a given set of etch conditions, there is an optimum concentration of oxidizing species at which the ratio between the bottom electrode etch rate and the hard mask etch rate goes through a maximum. The optimum reflects a balance between maintaining the oxide crust and limiting oxidative destruction of the hard mask. Because a high temperature is employed to achieve an acceptable etch rate while using low bias, the optimal concentration of oxidizing species in a process according to the present invention is generally lower than the optimal concentration for a standard, high bias etch process.

To the accomplishment of the foregoing and related ends, the following description and annexed drawings set forth in detail certain illustrative aspects and implementations of the invention. These are indicative of but a few of the various ways in which the principles of the invention may be employed. Other aspects, advantages and novel features of the invention will become apparent from the following detailed description of the invention when considered in conjunction with the drawings.

### BRIEF DESCRIPTION OF THE DRAWINGS

FIG. 1 is a diagram illustrating an exemplary prior art 1T/1C FeRAM memory cell.

FIG. 2 is a diagram illustrating an exemplary prior art 2T/2C FeRAM memory cell.

FIG. 3 is a flow chart illustrating a process according to one aspect of the present invention.

FIG. 4 is a high level schematic illustration of plasma etching the bottom electrode layer of a ferroelectric capacitor stack.

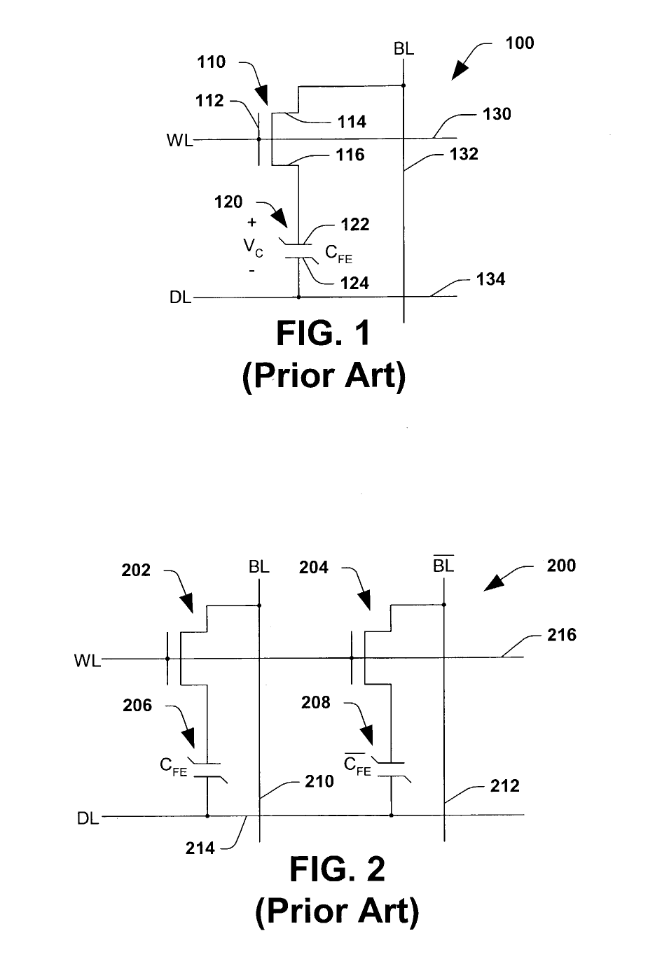

### DETAILED DESCRIPTION OF THE INVENTION

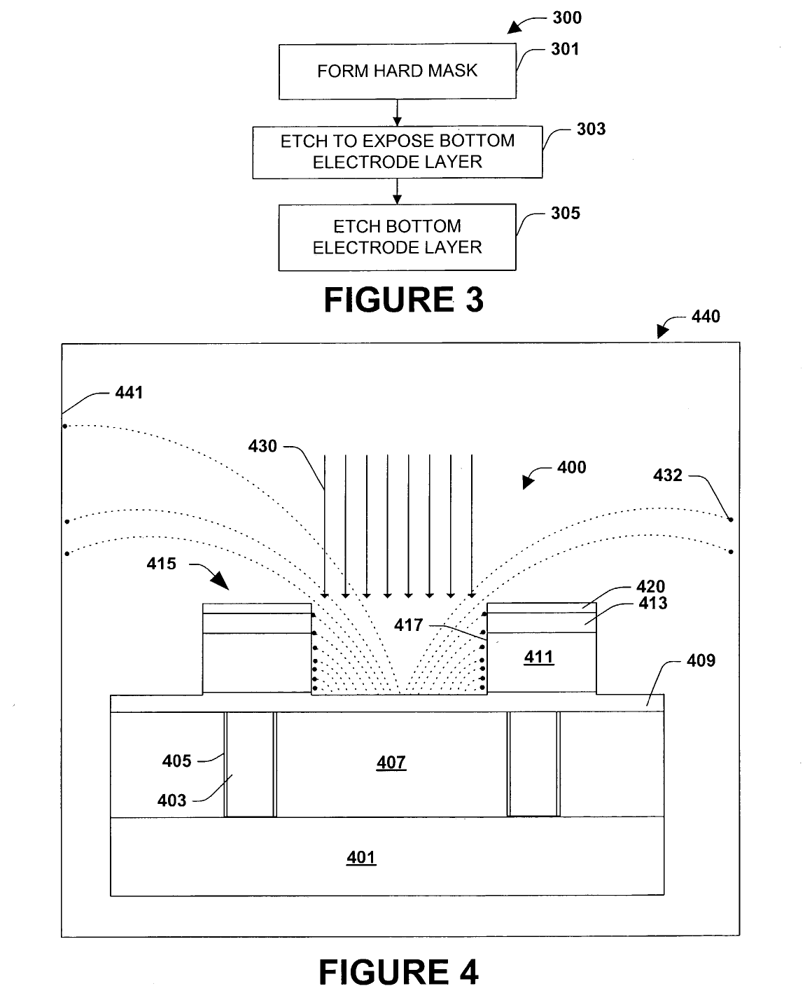

The present invention will now be described with reference to the attached drawings, wherein like reference numerals are used to refer to like elements throughout. FIG. 3 is a flow chart of a process 300 for etching a bottom electrode layer in a ferroelectric capacitor stack according to one aspect of the present invention. Process 300 includes forming a hard mask over the capacitor stack, act 301, etching the capacitor stack to expose the bottom electrode layer, act 303, and etching the bottom electrode layer, act 305.

The hard mask can include one or more layers of any suitable materials. In one embodiment, the hard mask includes a layer containing TiAlN. Act 301 involves forming the hard mask layers and lithographically patterning the hard mask to define the capacitor stack.

The capacitor stack includes at least a top electrode layer, a ferroelectric core, and a bottom electrode layer. The capacitor stack may also include additional layers, such as diffusion barrier layers. Of particular relevance to the present invention is the bottom electrode layer. The bottom electrode layer can include one or more sub-layers of any suitable material. Preferably, the bottom electrode layer comprises one or more metal or metal oxide sub-layers. Examples of suitable materials for the bottom electrode sub-layers include Pt, Pd, Au, Ag, Ir, Rh, Ru and oxides thereof. Specific examples include, without limitation, Pt, Pd, PdOₓ, IrPt alloys, Au, Ru, RuOₓ, (Ba,Sr,Pb)RuO3, (Sr,Ba,Pb)IrO3, Rh, RhOₓ, LaSrCoO₃, (Ba,Sr)RuO₃, or LaNiO₃ In one embodiment, the bottom electrode layer comprises sub-layers of Ir and IrO₂.

The preferred thickness of the bottom electrode layer is from about 10 nm to about 200 nm. The preferred thickness for an oxide electrode sub-layer is from about 20 nm to about 100 nm. The preferred thickness of a noble metal electrode sub-layer is from about 10 nm to about 100 nm. For example, the bottom electrode layer can include a 20 nm iridium sub-layer and a 30 nm iridium oxide sub-layer. Electrode layers can be sputter deposited using, for example, an iridium target at a temperature in the range from about 500° C. to about 550° C. Iridium is deposited in an inert atmosphere, such as Ar, with essentially no oxygen. Iridium oxide is deposited by including from about 30 to about 50 mole percent oxygen in the atmosphere.

The ferroelectric core can include any suitable material. Options include Pb(Zr,Ti)O₃ (PZT), doped PZT with donors (Nb, La, Ta) acceptors (Mn, Co, Fe, Ni, Al) and/or both, PZT doped and alloyed with SrTiO₃, BaTiO₃ or CaTiO₃, strontium bismuth tantalate (SBT) and other layered perovskites such as strontium bismuth niobate tantalate (SBNT) or bismuth titanate, BaTiO₃, PbTiO₃, Bi₂TiO₃ etc.

Act 303 is etching the capacitor stack using the patterned hard mask, including the top electrode layer and the ferroelectric core, to expose the bottom electrode layer. The etch conditions for the top electrode layer and the ferroelectric core can be the same as used to etch the bottom electrode layer, however, it is more common to tailor the etch conditions to the materials being etched. The point at which the bottom electrode layer is exposed can be determined in a variety of ways, including, for example, monitoring the composition of gas exhausted from a plasma etching chamber.

Act 305 is etching the bottom electrode layer. FIG. 4 illustrates this process for a device 400 in a plasma etching chamber 440. Device 400 includes a substrate 401 in which transistors (not shown) for ferroelectric memory cells are formed, conductive plugs 403, diffusion barriers 405, and a dielectric 407. The device 400 further comprises a bottom electrode layer 409, a ferroelectric core 411, and a top electrode layer 413. The bottom electrode layer 409, the ferroelectric core 411, and the top electrode layer 413 form capacitor stacks 415. A hard mask, 420, has been formed over the capacitor stacks 415. Reactive species from a plasma 430 strikes the bottom electrode layer 409 and causes particles 432 to be released. Particles 432 strike sidewalls 417 of the capacitor stacks 415 and sidewalls 441 of the chamber 440.

Plasma etching of the bottom electrode layer can cause shorting of the capacitor stacks. With reference to FIG. 4, the particles 432 released from the bottom electrode layer 409 encounter the sidewalls 417 of the capacitor stacks 415 and the sidewalls 441 of the chamber 440. In a conventional plasma etch process employing a halogen gas, the particles 432 deposit to form substantially conductive layers on the capacitor sidewalls 417 and the chamber sidewalls 441. A substantially conductive layer on the capacitor sidewalls 417 causes shorting. A substantially conductive layer on the chamber sidewalls 441 reduces plasma power. In the present context, shorting includes anything from an unacceptably high leakage current through a complete failure of the capacitor to operate.

Including an oxygen source which also contains carbon, such as carbon monoxide or carbon dioxide in the chamber atmosphere during etching improves the situation. The carbon monoxide or carbon dioxide causes reactions with the metal 432 to mitigate the build-up of a conductive layer on the chamber sidewalls 441. More particularly, the plasma products of the carbon monoxide or carbon dioxide addition react with the Ir metal 432 to form a material that is non-conductive and/or does not deposit on the chamber sidewalls 441. A conductive layer, however, can still form along the capacitor stack sidewalls 417 either because the flux of particles striking the capacitor sidewalls is greater than the flux of particles striking the chamber sidewalls or because it takes less time for the particles 432 to reach the capacitor sidewalls 417, giving the particles 432 less time to react. A competition exists between the rate at which conductive material from the bottom electrode layer 409 reacts with carbon monoxide or carbon dioxide and the rates at which the conductive material releases from the bottom electrode layer 409 and deposits on the sidewalls.

In yet another alternative embodiment, the conductive side wall layer deposition rate may be sufficient to result in a net capacitor side wall deposition, however, the composition of the conductive side wall material is such that it is readily removable, for example, with a subsequent clean operation. For example in the case of an Ir or Ir/IrOx bottom electrode stack, the carbon monoxide or carbon dioxide substantially prevents iridium oxide from forming on the side walls. Instead, in one case iridium chloride formed thereon, and it was found in such instances that the unwanted side wall material was readily removed with a subsequent clean. For example, a subsequent wet clean using a solvent or de-ionized water, for example, may be employed, and such a process is contemplated as falling within the scope of the present invention.

According to one aspect of the invention, the etch bias is set to a relatively low level whereat the ratio between the reaction and deposition rates is such that a substantially conductive layer does not form on the capacitor stack sidewalls. The bias is the electrical driving force that controls the energy of the reactive species of the plasma. In a typical plasma etching apparatus, the operator does not know the true bias but has control over a power supply that is in proportion to the true bias. By experimentally varying the power, a setting corresponding to a low bias can be determined.

A high bias generally corresponds to 450 Watts on an Applied Materials Metal Etch DPS II Centura 300 (hereinafter the “standard etcher”). A low bias generally corresponds to about 250 Watts or less on the standard etcher. In one embodiment, the bias corresponds to about 150 Watts or less on the standard etcher. In another embodiment, the bias corresponds to about 100 Watts or less on the standard etcher. In a further embodiment, the bias corresponds to about 50 Watts or less on the standard etcher. A typical source power level for the standard etcher is in the range from about 1150 to about 1250 Watts.

If a manufacturer recommends a bias for etching a metal electrode, the recommended bias will generally be high. Higher biases are favored because metal etch rates tends to be problematically low and higher biases increase the etch rate. Generally, a high bias results in a large electric field in the chamber, resulting in ions being accelerated toward the wafer at a high rate, thereby making the etch have a substantial physical component. A low bias is typically about half the recommended bias or less.

According to another aspect of the invention, in order to achieve a satisfactory etch rate at low bias, etch conditions are adjusted to where chemical etching significantly contributes to the overall etch rate. In one embodiment, a temperature of at least about 300° C. is employed. In another embodiment, a temperature of at least about 350° C. is employed. Preferably, the etch rate is at least about 30 nm/min, more preferably at least about 55 nm/min, and still more preferably at least about 80 nm/min.

The etch rate is preferably at least about 10% chemical, more preferably at least about 20% chemical, and still more preferably at least about 30% chemical. The chemical contribution to the etch rate can be determined by measuring the etch rate at low temperature, where the chemical component is negligible. The physical etching rate can be extrapolated to a temperature at which the chemical component is significant by fitting the rate at several low temperatures to an Arrhenius expression. Generally, the physical etch rate depends very little or not at all on temperature.

The atmosphere for plasma etching the bottom electrode layer includes a halogen compound and an oxygen compound or mixture, such as O₂, carbon monoxide, carbon dioxide or a combination thereof. Examples of suitable halogen compounds include chlorine and fluorine compounds. Typically, the plasma includes Cl₂ and CO. Preferably the atmosphere includes at least about 10 mole % halogen compound, more preferably over about 15 mole %, and still more preferably at least about 20 mole %. Preferably the atmosphere includes at least about 10 mole % CO or CO₂, more preferably at least about 25 mole %, and still more preferably at least about 35 mole %. Mole percentages are based on the composition fed to the plasma etching chamber. The atmosphere can also include inert gases such as N₂ or Ar. Any suitable pressure can be employed the pressure being typically in the range from about 10 to about 20 mT.

The atmosphere typically also includes a component more oxidizing than CO or CO₂, such as O₂ or O₃. A further aspect of the invention is including a sufficient amount of an oxidizing component in the atmosphere to improve the selectivity between the hard mask and the bottom electrode. This aspect of the invention is particularly useful when the hard mask contains TiAlN. The oxidizing component reacts to form an oxide crust over the hard mask. Oxides of hard mask materials such as TiAlN etch more slowly than their reduced counterparts. In this regard, the oxidizing component tends to improve the selectivity between the hard mask and the bottom electrode layer. On the other hand, oxidation itself can consume the hard mask, tending to degrade the selectivity. Generally, there is an optimal concentration for an oxidizing component at which the selectivity between the bottom electrode layer and the hard mask goes through a maximum.

In one embodiment, the atmosphere includes from about 5 to about 70 mole % of a component more oxidizing than CO or CO₂. In another embodiment, the atmosphere includes from about 15 to about 50 mole % of the more oxidizing component. In a further embodiment, the atmosphere includes from about 30 to about 40 mole % of the more oxidizing component. These concentration are particularly suitable for a TiAlN hard mask with little or no oxygen content. Lower concentrations of the more oxidizing component are preferred when the hard mask has a significant oxygen content from the outset.

Oxygen is commonly used in plasma etching processes. At the low bias/high temperature conditions of the present invention, however, a given oxidation rate can be achieved at a lower oxygen concentration. An advantage of lower oxygen concentration is that it permits the use of a higher CO or CO₂ concentration. Higher concentrations of CO or CO₂ allow etching to take place more rapidly while maintaining a balance between chemical and physical etch rates at which the build-up of a conducting layer on the capacitor stack sidewalls can be prevented.

Although the invention has been shown and described with respect to a certain aspect or various aspects, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several aspects of the invention, such feature may be combined with one or more other features of the other aspects as may be desired and advantageous for any given or particular application. Furthermore, to the extent that the term “includes” is used in either the detailed description or the claims, such term is intended to be inclusive in a manner similar to the term “comprising.”

What is claimed is:

1. A method of etching a bottom electrode layer in a ferroelectric capacitor stack, comprising:
forming a hard mask over the ferroelectric capacitor stack;
etching the capacitor stack to expose the bottom electrode layer; and
plasma etching the bottom electrode layer at a low bias with an atmosphere comprising a halogen compound and an oxygen source containing carbon.

2. The method of claim 1, wherein the oxygen source containing carbon comprises carbon monoxide or carbon dioxide.

3. The method of claim 2, wherein the hard mask comprises TiAlN and the atmosphere further comprises a more oxidizing component than carbon monoxide or carbon dioxide that is effective to oxidize the hard mask and improve etch selectivity between the bottom electrode layer and the hard mask during the plasma etching of the bottom electrode layer.

4. The method of claim 2, wherein the atmosphere comprises at least about 10 mole % Cl₂, at least 0-10 mole % O₂, and at least about 10 mole % CO or CO₂.

5. The method of claim 1, wherein plasma etching takes place at a temperature of at least about 300° C.

6. The method of claim 1, wherein the bias corresponds to about 250 Watts or less on a standard etcher.

7. The method of claim 1, wherein conductive material from the bottom electrode layer deposits on side walls of the capacitor stack, but the deposited material reacts with the atmosphere at a rate sufficient to prevent a significant accumulation of conductive material on the side walls.

8. The method of claim 1, wherein the capacitor stack has sidewalls and conductive material from the bottom electrode does not deposit on the side walls in an amount sufficient to cause shorting.

9. The method of claim 1, wherein the bottom electrode layer comprises an iridium or iridium oxide sub-layer.

10. The method of claim 1, wherein the capacitor stack has sidewalls and conductive material from the bottom electrode does deposit on the sidewalls, further comprising:
performing a clean operation after the plasma etching, the clean operation operable to remove the conductive material from the sidewalls.

11. A method of etching a bottom electrode layer in a ferroelectric capacitor stack, comprising:
patterning a top electrode layer and a ferroelectric dielectric layer portion of the ferroelectric capacitor stack; and
with an atmosphere comprising a halogen compound and an oxygen source containing carbon, plasma etching at an energy and temperature at which both chemical and physical etching of the bottom electrode layer are substantial.

12. The method of claim 11, wherein the oxygen source containing carbon comprises carbon monoxide or carbon dioxide.

13. The method of claim 11, wherein the plasma etch rate is at least about 20% chemical.

14. The method of claim 11, wherein the bottom electrode layer comprises an iridium or iridium oxide sub-layer.

15. The method of claim 11, wherein the energy corresponds to about 250 Watts or less on a standard etcher.

16. The method of claim 12, wherein the ferroelectric capacitor stack comprises a hard mask comprising TiAlN and the atmosphere further comprises a more oxidizing component than carbon monoxide or carbon dioxide that is effective to oxidize the hard mask and improve etch selectivity between the bottom electrode layer and the hard mask.

17. A method of etching a bottom electrode layer in a ferroelectric capacitor stack, comprising:
forming a hard mask over the ferroelectric capacitor stack;
etching the capacitor stack to expose the bottom electrode layer; and
using gases comprising a halogen compound and an oxygen source containing carbon, plasma etching the bottom electrode layer to produce an etch byproduct;
wherein plasma etching the bottom electrode layer does not leave the byproduct in a configuration to cause shorting between a top electrode layer of the capacitor stack and the bottom electrode layer along sidewalls of the capacitor stack.

18. The method of claim 17, wherein the oxygen source containing carbon comprises carbon monoxide or carbon dioxide.

19. The method of claim 17, wherein the etch byproduct is conductive and deposits on the sidewalls in a quantity sufficient to cause shorting, but the deposited byproduct reacts with the gases at a rate that prevents accumulation of conductive material sufficient to cause shorting.

20. The method of claim 19, wherein the deposited byproduct reacts with the gases to form a further byproduct that releases from the sidewalls during the process of plasma etching the bottom electrode layer.

21. The method of claim 19, wherein the deposited byproduct reacts with the gases to form a further byproduct that is non-conductive.

22. The method of claim 17, wherein the etch byproduct is non-conductive.

23. The method of claim 17, wherein the capacitor stack has sidewalls and conductive material from the bottom electrode does deposit on the sidewalls, further comprising:
performing a clean operation after the plasma etching, the clean operation operable to remove the conductive material from the sidewalls.

24. The method of claim 17, wherein the bottom electrode layer comprises an iridium or iridium oxide sub-layer.

25. The method of claim 17, wherein the ferroelectric capacitor stack comprises a hard mask comprising TiAlN and the gases further comprises a more oxidizing component that is effective to oxidize the hard mask and improve etch selectivity between the bottom electrode layer and the hard mask.
